(19) United States
(12) Patent Application Publication
(10) Pub. No.: US 2013/0168066 A1
(43) Pub. Date: Jul. 4, 2013

(54) ENCLOSURE WITH AIRFLOW GUIDING DUCT

(71) Applicants: LIANG-CHIN WANG, Tu-Cheng (TW); YU-MING XIAO, Wuhan City (CN); ZAN LI, Wuhan City (CN); ZHI-JUN FU, Wuhan City (CN)

(72) Inventors: LIANG-CHIN WANG, Tu-Cheng (TW); YU-MING XIAO, Wuhan City (CN); ZAN LI, Wuhan City (CN); ZHI-JUN FU, Wuhan City (CN)

(21) Appl. No.: 13/667,250

(22) Filed: Nov. 2, 2012

(30) Foreign Application Priority Data
Dec. 29, 2011 (CN) 201110450574.5

(51) Int. Cl. H05K 7/20

(52) U.S. Cl. 165/122

(57) ABSTRACT

An enclosure includes a chassis and an airflow guiding duct. The chassis includes a bottom plate and a rear plate connected to the bottom plate. The bottom plate defines two cutouts providing a pivot point. Two latch pieces with holes are located on the rear plate. The airflow guiding duct pivots on the bottom plate cutouts. Resilient pieces extend from each sidewall of the guiding duct. Each of the two resilient pieces is engaged in the latch holes, to secure the airflow guiding duct to the chassis. Each of the two resilient pieces is deformable to allow quick disengagement from the latch hole, to release the airflow guiding duct.

### BACKGROUND

1. Technical Field

The present disclosure relates to chassis assemblies, and more particularly to an enclosure with a airflow guiding duct.

2. Description of Related Art

A fan is generally mounted in an chassis of an electronic device, such as a computer, for dissipating heat generated from electronic components in the electronic device. An airflow guiding duct is usually mounted in the chassis, for guiding the airflow, increasing efficiency of the fan of bringing the heat out of the chassis. The airflow guiding duct of related art is mounted in the chassis with fasteners, such as screws or bolts. This method for mounting the airflow guiding duct involves many fasteners and adds cost of labor. Thus, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a fan and an enclosure including a chassis and an airflow guiding duct.

FIG. 2 is similar to FIG. 1, but viewed from a different aspect.

FIG. 3 is an enlarged view of portion III of FIG. 2.

FIG. 4 is similar to FIG. 1, but showing the fan and an airflow guiding duct in assembly.

FIG. 5 is an assembled view of FIG. 2, and the airflow guiding duct being in the second position.

FIG. 6 is similar to FIG. 5, and the airflow guiding duct being in the first position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

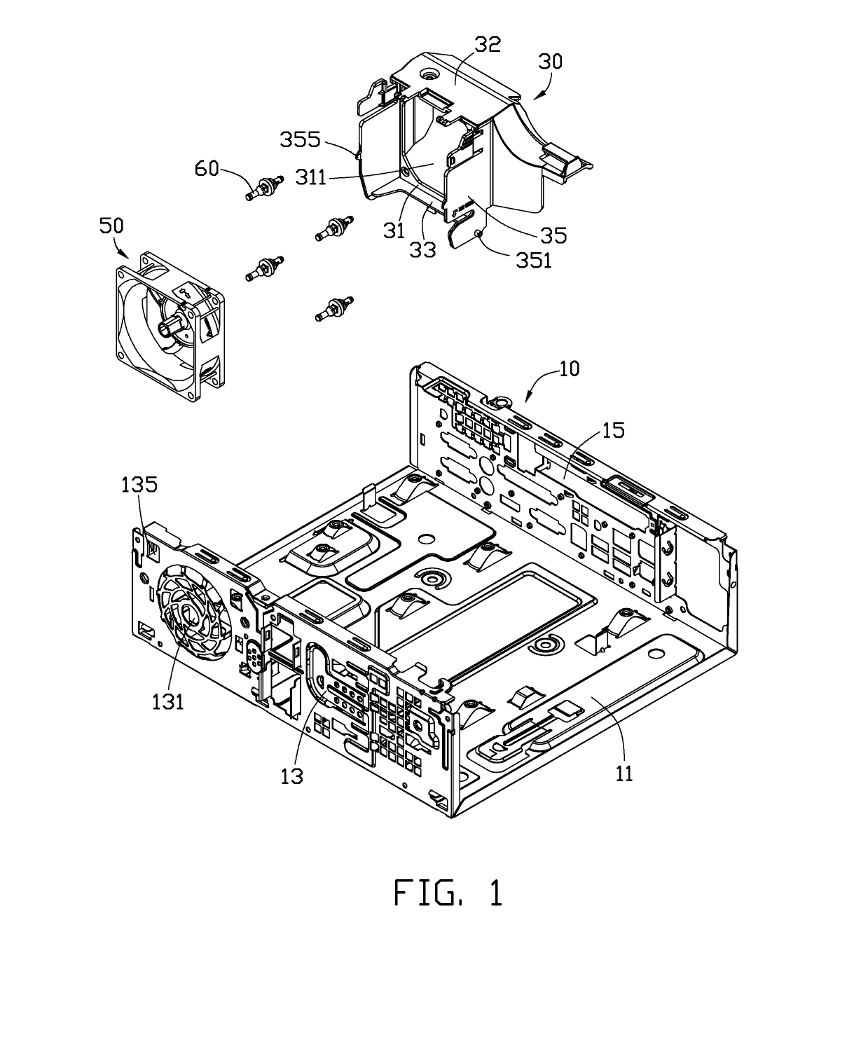

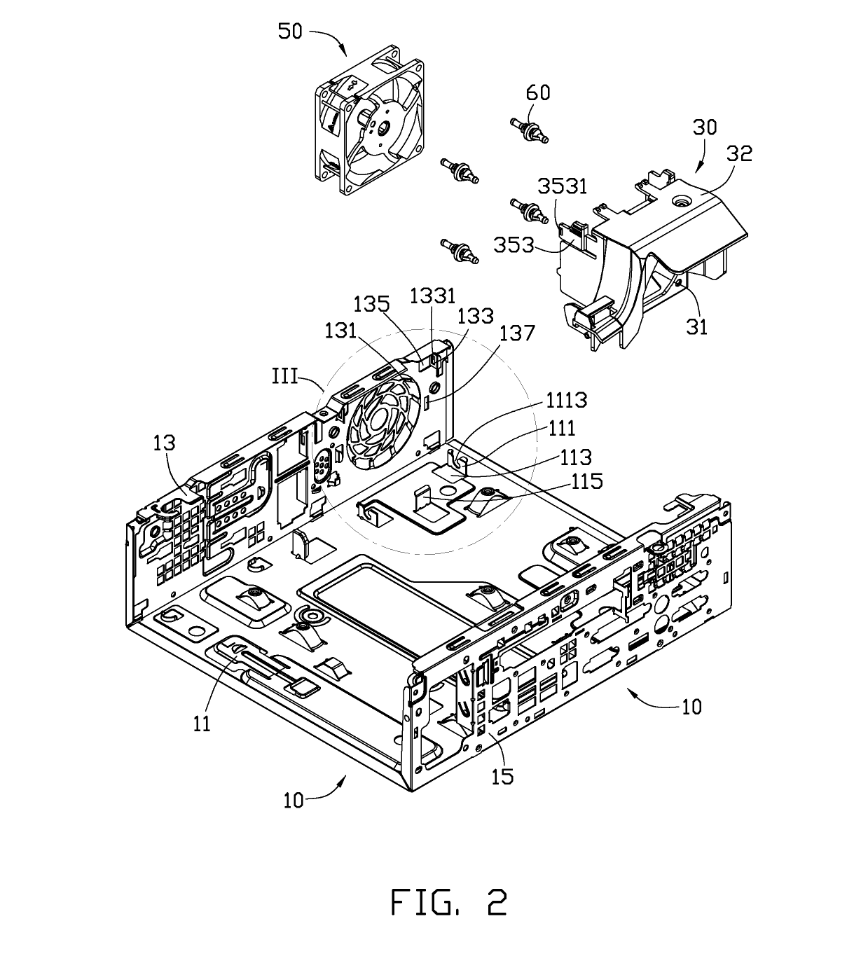

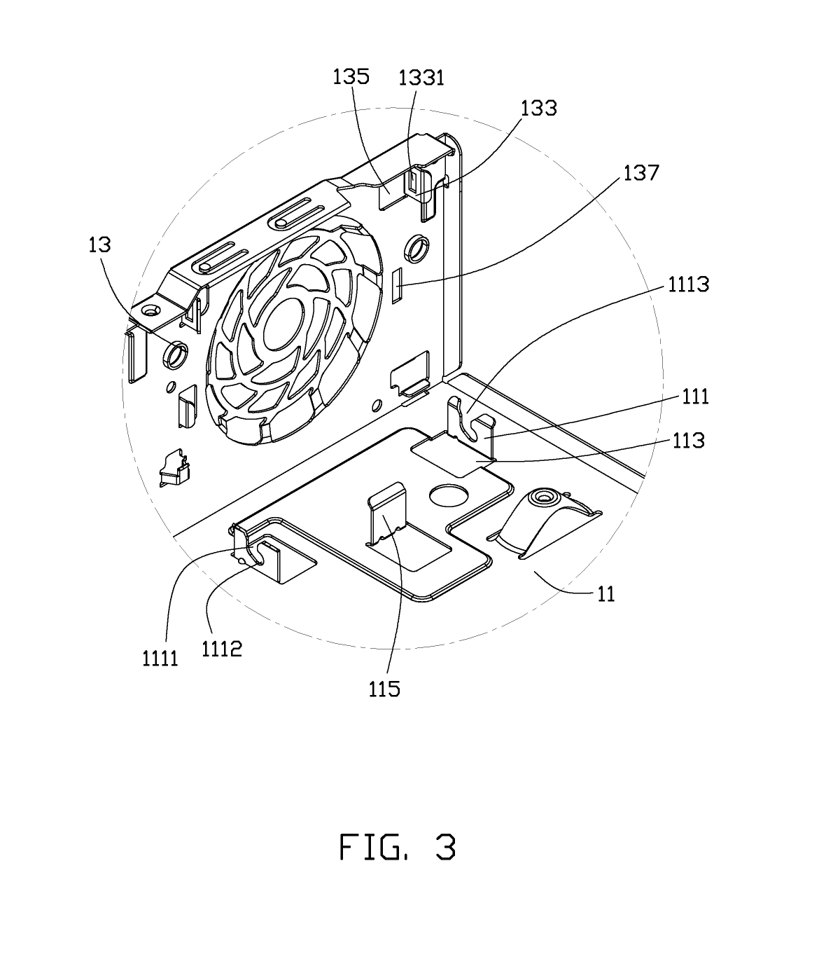

Referring to FIGS. 1-3, an enclosure in accordance with an embodiment includes a chassis 10 and an airflow guiding duct 30. The airflow guiding duct 30 receives a fan 50.

The chassis 10 includes a bottom plate 11, a rear plate 13, and a front plate 15. The rear plate 13 and the front plate 15 extend from two opposite sides of the bottom plate 11. The rear plate 13 and the front plate 15 are substantially perpendicular to the bottom plate 11. The bottom plate 11 defines two rectangular holes 113. Two pivot pieces 111 are located on the bottom plate 11. Each of the two pivot pieces 111 extends from an edge of each of the two rectangular holes 113. The two pivot pieces 111 are substantially parallel to each other and perpendicular to the bottom plate 11. Each of the two pivot pieces 111 defines a cutout 1113. The cutout 1113 includes a wide portion 1111 and a narrow portion 1112. The wide portion 1111 has a first extending direction. The narrow portion 1112 has a second extending direction. In one embodiment, the first extending direction is substantially vertical, and an obtuse angle is defined between the first extending direction and the second extending direction. A positioning piece 115, between the two pivot pieces 111, is located on the bottom plate 11, to block the airflow guiding duct 30 in a particular location.

The rear plate 13 defines a ventilation area 131 and two apertures 132 at two corners of the ventilation area 131. Two latch pieces 133 extend from an edge of each of the two apertures 132. Each of the two latch pieces 133 defines a latch hole 1331. The two latch pieces 133 are parallel to each other and perpendicular to the rear plate 13. The rear plate 13 further defines two positioning holes 137 located on opposite sides of the ventilation area 131. A first distance between the two latch pieces 133 is substantially equal to a second distance between the two positioning holes 137.

The airflow guiding duct 30 includes a frame 31, a top wall 32, a bottom wall 33, and two sidewalls 35. The frame 31 defines an opening 311. The top wall 32 and the bottom wall 33 extend from opposite sides of the frame 31. The two sidewalls 35 extend from the other two opposing sides of the frame 31. The fan 50 can be secured to the frame 31 via a plurality of locking members 60 and is surrounded by the top wall 32, the bottom wall 33, and the two sidewalls 35. The airflow guiding duct 30 guides an airflow from the fan 50 through the opening 311 to the chassis 10. The airflow guiding duct 30 further includes two pivot posts 351 and two resilient pieces 353. A pivot post 351 protrudes from each of the two sidewalls 35. The resilient pieces 353 extend from the sidewalls 35. A protrusion 3531 is located on distal end of each of the two sidewalls 35. A positioning tab 355 extends from each of the two sidewalls 35. A third distance between the two resilient pieces 353 is equal to the second distance. A fourth distance between the positioning tabs 355 is equal to the second distance.

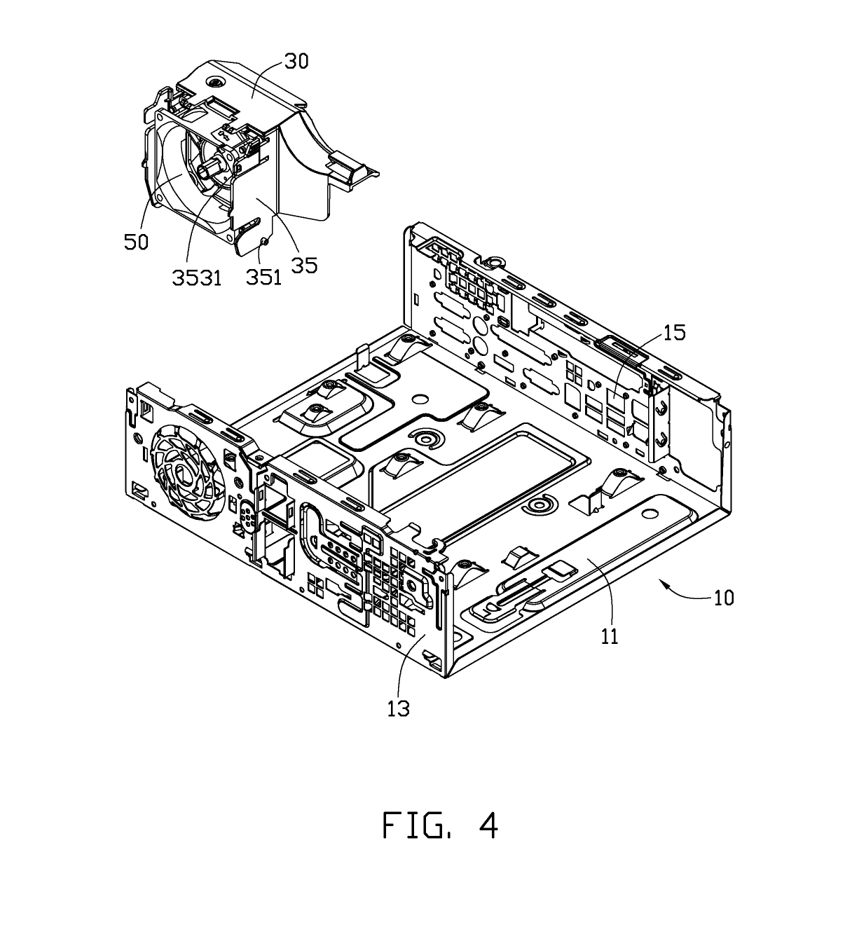

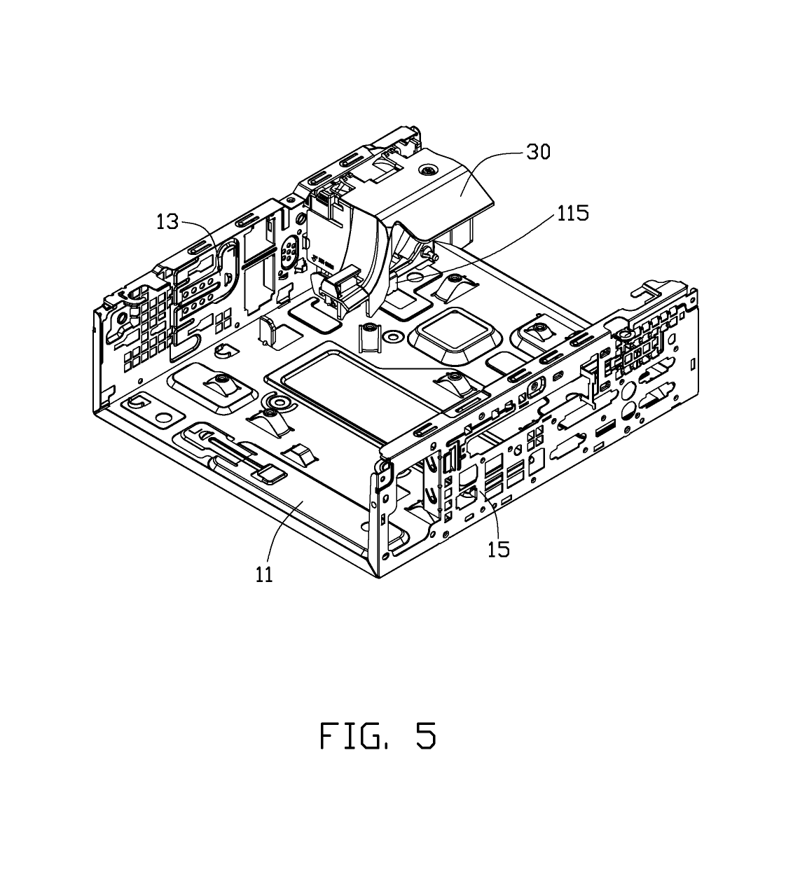

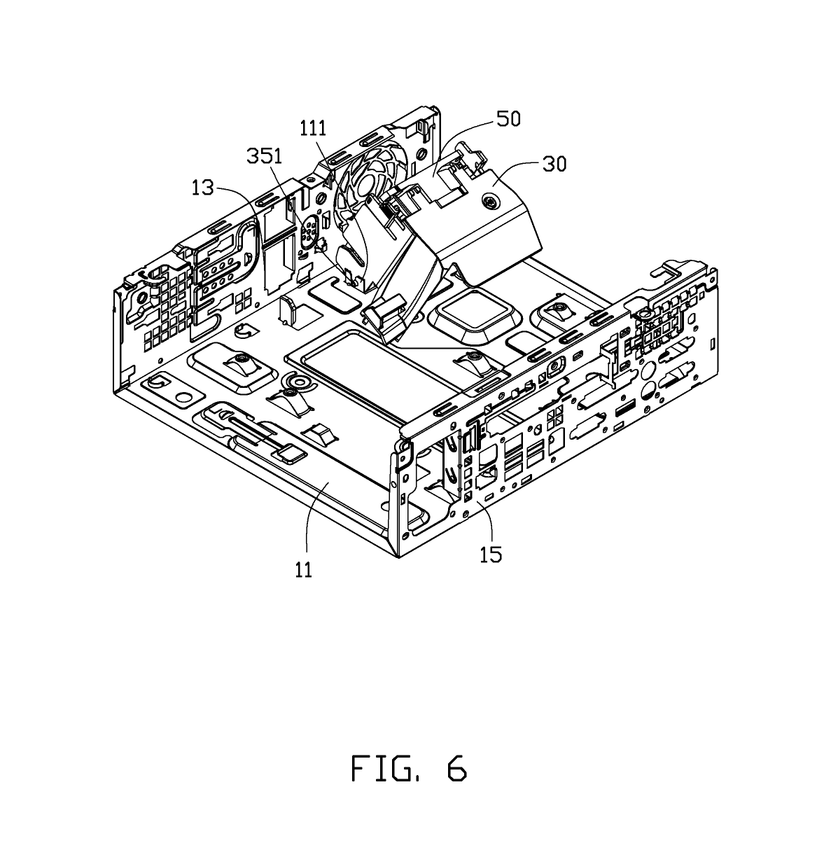

Referring to FIGS. 4-6, in assembly, the airflow guiding duct 30 is placed on an inner side of the rear plate 13. Each of the two pivot posts 351 extends through the wide portion 1111, to be engaged in the narrow portion 1112 of each of the two pivot pieces 1111. The airflow guiding duct 30 is rotated in a first direction around the two pivot posts 351. The two latch pieces 133 bias each protrusion 3531 to resiliently deform the two resilient pieces 353, until each protrusion 3531 is aligned with each latch hole 1331. The two resilient pieces 353 bend to allow engagement of each protrusion 3531 into each latch hole 1331, thus the airflow guiding duct 30 is in a first position. The positioning tabs 355 are inserted into the positioning holes 137. The airflow guiding duct 30 is thereby secured to the chassis 10.

In disassembly, the two resilient pieces 353 are resiliently deformable to allow disengagement of each protrusion 3531 from each latch hole 1331. The airflow guiding duct 30 is rotated around the two pivot posts 351 in a second direction opposite to the first direction, until each protrusion 3531 disengages from the latch pieces 133, thus the airflow guiding duct 30 is in the second position. The airflow guiding duct 30 is easily detachable from the chassis 10.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. An enclosure, comprising:
a chassis comprising a bottom plate and a rear plate connected to the bottom plate; the bottom plate defining two cutouts, two latch pieces being located on the rear plate, and each of the two latch pieces defining a latch hole;
an airflow guiding duct pivotably secured to the chassis; the airflow guiding duct comprising two sidewalls, two pivot posts, and two resilient pieces; each of the two pivot posts protrudes from each of the two sidewalls; each of the two resilient pieces extend from each of the two sidewalls; each of the two pivot posts engaged in each of the two cutouts; and each of the two resilient pieces is engaged in the latch hole of each of the two latch pieces, to secure the airflow guiding duct to the chassis; and each of the two resilient pieces is resiliently deformable to disengage from the latch hole of each of the two latch pieces, to release the airflow guiding duct.

2. The enclosure of claim 1, wherein a protrusion is located on each of the two resilient pieces, the protrusion of each of the two resilient pieces is engaged in each of the two latch holes, and the two resilient pieces are resiliently deformed to disengage the protrusion from the two latch holes of the two latch pieces.

3. The enclosure of claim 1, wherein the two latch pieces are substantially parallel to each other and perpendicular to the rear plate.

4. The enclosure of claim 1, wherein two pivot pieces are located on the bottom plate, and each of the two cutouts is defined in each of the two pivot pieces.

5. The enclosure of claim 4, wherein the two pivot pieces are substantially parallel to each other and perpendicular to the bottom plate.

6. The enclosure of claim 1, wherein the airflow guiding duct further comprises a frame with an opening, the airflow guiding duct guides airflow to the chassis via the opening.

7. The enclosure of claim 6, wherein a supporting piece is located on the bottom plate, and the supporting piece abuts the frame.

8. The enclosure of claim 1, wherein each of the two cutouts comprises a wide portion and a narrow portion communication with the wide portion, and each pivot post extends through the wide portion to be engaged in the narrow portion.

9. The enclosure of claim 8, wherein the wide portion has a first extending direction and the first extending direction is substantially perpendicular to the bottom plate.

10. The enclosure of claim 9, wherein the narrow portion has a second extending direction, and an obtuse angle is defined between the first extending direction and the second extending direction.

11. An enclosure, comprising:
a chassis comprising a bottom plate and a rear plate connected to the bottom plate; the bottom plate defining two cutouts, two latch pieces being located on the rear plate, and each of the two latch pieces defining a latch hole;
an airflow guiding duct, the airflow guiding duct comprising two sidewalls, two pivot posts and two resilient pieces, each of the two pivot posts protrudes from each of the two sidewalls and engaged in each of the two cutouts, and each of the two resilient pieces extending from each of the two sidewalls; the airflow guiding duct is rotatable between a first position and a second position, when the airflow guiding duct is in the first position, each of the two resilient pieces is engaged in each latch hole; and when the airflow guiding duct is in the second position, each of the two resilient pieces is resiliently deformable to disengage from the latch hole.

12. The enclosure of claim 11, wherein a protrusion is located on each of the two resilient pieces, the protrusion is engaged in the latch hole, and the two resilient pieces are resiliently deformed to disengage the protrusion from the latch hole.

13. The enclosure of claim 11, wherein the two latch pieces are substantially parallel to each other and perpendicular to the rear plate.

14. The enclosure of claim 11, wherein two pivot pieces are located on the bottom plate, and each of the two cutouts is defined in each of the two pivot pieces.

15. The enclosure of claim 14, wherein the two pivot pieces are substantially parallel to each other and perpendicular to the bottom plate.

16. The enclosure of claim 11, wherein the airflow guiding duct further comprise a frame with an opening, the airflow guiding duct guides airflow by the opening to the chassis.

17. The enclosure of claim 16, wherein a supporting piece is located on the bottom plate, and the supporting piece abuts the frame.

18. The enclosure of claim 1, wherein each of the two cutouts comprises a wide portion and a narrow portion communication with the wide portion, and each pivot post extends through the wide portion to be engaged in the narrow portion.

19. The enclosure of claim 18, wherein the wide portion has a first extending direction and the first extending direction is substantially perpendicular to the bottom plate.

20. The enclosure of claim 19, wherein the narrow portion has a second extending direction, and an obtuse angle is defined between the first extending direction and the second extending direction.
